(19) United States
(12) Patent Application Publication
(10) Pub. No.: US 2024/0061986 A1
(43) Pub. Date: Feb. 22, 2024

(54) METHOD AND APPARATUS FOR COUPLING SUPERCONDUCTING QUBIT, ELECTRONIC DEVICE, COMPUTER MEDIUM

(71) Applicant: Beijing Baidu Netcom Science Technology Co., Ltd., Beijing (CN)

(72) Inventors: Yuxuan WANG, Beijing (CN); Lijing Jin, Beijing (CN)

(73) Assignee: Beijing Baidu Netcom Science Technology Co., Ltd., Beijing (CN)

(21) Appl. No.: 18/386,528

(22) Filed: Nov. 2, 2023

(30) Foreign Application Priority Data
Jan. 31, 2023 (CN) 202310107089.0

(51) Int. Cl. G06F 30/392; G06N 10/40

(52) U.S. Cl. CPC G06F 30/392; G06N 10/40

(57) ABSTRACT

The present disclosure provides a method and apparatus for coupling a superconducting qubit. The method includes: determining a target coupling strength between a target read cavity and a qubit, a first target frequency of the qubit, and a second target frequency of the target read cavity; initializing a read coupling port configuration layout based on a configuration of the qubit, a relative position of the qubit to the target read cavity; calculating a to-be-measured coupling strength between the qubit and the read coupling port, based on the read coupling port configuration layout, the first target frequency, and the second target frequency; and in response to detecting that the to-be-measured coupling strength and the target coupling strength satisfy a preset condition, generating, based on the second target frequency and the read coupling port configuration layout, a complete layout comprising the qubit and the target read cavity.

### CROSS-REFERENCE TO RELATED APPLICATIONS

The present application claims the priority of Chinese Patent Application No. 202310107089.0, titled “METHOD AND APPARATUS FOR COUPLING SUPERCONDUCTING QUBIT, ELECTRONIC DEVICE, COMPUTER MEDIUM”, filed on Jan. 31, 2023, the content of which is incorporated herein by reference in its entirety.

### TECHNICAL FIELD

The present disclosure relates to the technical field of quantum computing, in particular to the technical field of superconducting quantum chips, and more particularly, to a method and apparatus for coupling a superconducting qubit, an electronic device, a computer readable medium and a computer program product.

### BACKGROUND

As a core of quantum computing, quantum chips are significantly important. A core part in superconducting quantum chip design includes the design of a qubit and a read cavity. Here, the qubit serves as one unit of quantum computing, while the read cavity is another important unit used to indirectly read a state of the qubit. Main design indexes of the read cavity include a frequency of the read cavity itself, a quality factor of the read cavity, and a coupling strength between the read cavity and the qubit. For the coupling between the read cavity and the qubit, too weak coupling affects a read efficiency of the qubit, while too strong coupling introduces more noise to the qubit.

Currently, read coupling ports are often designed as black boxes in the industry. It is necessary to first design a preliminary version of a complete layout of the qubit and the read cavity, and then calculate the coupling strength between the qubit and the read cavity through electromagnetic simulation. A design in iterations of the read coupling port is based on a difference between the calculated coupling strength and a target, which is a very inefficient method in a design stage of the quantum chip.

### SUMMARY

A method and apparatus for coupling a superconducting qubit, an electronic device, a computer readable medium, and a computer program product are provided.

A method for coupling a superconducting qubit is provided, including: determining a target coupling strength between a target read cavity and a qubit, a first target frequency of the qubit, and a second target frequency of the target read cavity; initializing a read coupling port configuration layout based on a configuration of the qubit, a relative position of the qubit to the target read cavity, the read coupling port configuration layout being used to represent a layout of a positional relationship between the qubit and a read coupling port of the target read cavity; calculating a to-be-measured coupling strength between the qubit and the read coupling port, based on the read coupling port configuration layout, the first target frequency, and the second target frequency; and in response to detecting that the to-be-measured coupling strength and the target coupling strength satisfy a preset condition, generating, based on the second target frequency and the read coupling port configuration layout, a complete layout comprising the qubit and the target read cavity.

An apparatus for coupling a superconducting qubit is provided, including: a determination unit, configured to determine a target coupling strength between a target read cavity and a qubit, a first target frequency of the qubit, and a second target frequency of the target read cavity; an initialization unit, configured to initialize a read coupling port configuration layout based on a configuration of the qubit, a relative position of the qubit to the target read cavity, the read coupling port configuration layout being used to represent a layout of a positional relationship between the qubit and a read coupling port of the target read cavity; a calculation unit, configured to calculate a to-be-measured coupling strength between the qubit and the read coupling port, based on the read coupling port configuration layout, the first target frequency, and the second target frequency; and a generation unit, configured to, in response to detecting that the to-be-measured coupling strength and the target coupling strength satisfy a preset condition, generate, based on the second target frequency and the read coupling port configuration layout, a complete layout comprising the qubit and the target read cavity.

An electronic device is provided, including: one or more processors; and a storage apparatus storing one or more programs thereon, where the one or more programs, when executed by the one or more processors, cause the one or more processors to implement the method according to any implementation in the first aspect.

A non-transitory computer-readable medium storing a computer program thereon is provided, where the program, when executed by a processor, implements the method according to any implementation in the first aspect.

A computer program product is provided, including a computer program, where the computer program, when executed by a processor, implements the method according to any implementation in the first aspect.

It should be understood that contents described in this section are neither intended to identify key or important features of embodiments of the present disclosure, nor intended to limit the scope of the present disclosure. Other features of the present disclosure will become readily understood in conjunction with the following description.

### BRIEF DESCRIPTION OF THE DRAWINGS

The accompanying drawings are used for a better understanding of the present solution, and do not constitute a limitation to the present disclosure. In which:

FIG. 1 is a flowchart of an embodiment of a method for coupling a superconducting qubit according to the present disclosure;

FIG. 2 is a schematic structural diagram of a read coupling port configuration layout in an embodiment of the present disclosure;

FIG. 3 is a schematic structural diagram of a complete layout in an embodiment of the present disclosure;

FIG. 4 is a flowchart of another embodiment of the method for coupling a superconducting qubit according to the present disclosure;

FIG. 5 is a schematic structural diagram of an embodiment of an apparatus for coupling a superconducting qubit according to the present disclosure; and

FIG. 6 is a block diagram of an electronic device used to implement the method for coupling a superconducting qubit of embodiments of the present disclosure.

### DETAILED DESCRIPTION OF EMBODIMENTS

Example embodiments of the present disclosure are described below with reference to the accompanying drawings, where various details of the embodiments of the present disclosure are included to facilitate understanding, and should be considered merely as examples. Therefore, those of ordinary skills in the art should realize that various changes and modifications can be made to the embodiments described herein without departing from the scope and spirit of the present disclosure. Similarly, for clearness and conciseness, descriptions of well-known functions and structures are omitted in the following description.

In order to better understand the method provided by embodiments of the present disclosure, relevant concepts involved in the embodiments of the present disclosure will be described in detail below.

A quantum chip integrates a quantum circuit on a substrate, carrying a function of quantum information processing.

As the limit of classical Moore's law is approaching, quantum computing is considered to be the next generation of novel computing mode, which is expected to demonstrate a greater computing power than classical computing in many complex problems, providing up to exponential acceleration in problem-solving efficiency improvement. It is rather worth noting that the realization of quantum applications is highly dependent on the development of quantum hardware. In terms of the technical realization of quantum hardware, several different technical schemes exist in the industry, such as superconducting circuits, ion traps, semiconductors, and optical quantum systems. Benefiting from a good scalability and mature semiconductor processes, the design, research and manufacture of superconducting quantum chips integrating multiple superconducting qubits are of great importance. Many innovative companies or research organizations in the field of quantum computing have launched their own superconducting quantum chips.

Recently, the number of qubits integrated on a superconducting quantum chip has been increasing, growing from a few, tens to hundreds and thousands, and then a subsequent goal is to realize the integration of millions of qubits.

A core part of superconducting quantum chip design includes the design of a qubit and a read cavity. Here, the qubit serves as one unit of quantum computing, while the read cavity is another important unit used to indirectly read a state of the qubit. Main design indexes of the read cavity include a frequency of the read cavity itself, a quality factor of the read cavity, and a coupling strength between the read cavity and the qubit. The frequency of the read cavity itself and the quality factor may be adjusted by regulating its own length and coupling to external. For the coupling between the read cavity and the qubit, too weak coupling affects a read efficiency of the qubit, and too strong coupling introduces more noise to the qubit, thus affecting a coherence time of the qubit. Therefore, a coupling port between the read cavity and the qubit needs to be accurately designed to realize a specific target read coupling strength.

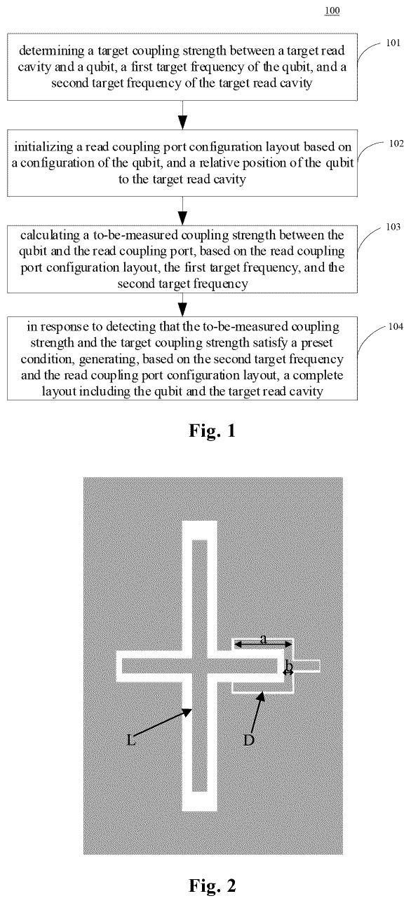

FIG. 1 shows a flow 100 of an embodiment of a method for coupling a superconducting qubit according to the present disclosure, and the method for coupling a superconducting qubit includes the following steps: 101 to 104.

Step 101, determining a target coupling strength between a target read cavity and a qubit, a first target frequency of the qubit, and a second target frequency of the target read cavity.

In the present embodiment, the core part of the superconducting quantum chip design includes the design of the qubit and the read cavity. A two-level structure of the qubit is accurately designed as a quantum computing unit, while the read cavity is another important component used to indirectly read the state of the qubit. The read cavity is directly coupled to the superconducting qubit to form a relationship of dispersion coupling, i.e., a frequency difference between the qubit and the read cavity is much larger than a coupling strength between the two. Dispersion coupling requires that the frequency difference between the qubit and the read cavity is greater than 1 GHz, and the target coupling strength is usually between 30 and 60 MHz.

Dispersion coupling may lead to a dispersion shift between the qubit and the read cavity, and a shift equation is as shown in equation (1).

$$𝒳 = \frac{{g}^{2}}{Δ} \qquad ( 1 )$$

where, in equation (1), Δ is an amount of frequency detuning of the qubit with the read cavity, g is the coupling strength between the qubit and the read cavity, and χ is an amount of dispersion shift. From equation (1), it can be seen that relevant information of the qubit may be indirectly acquired through a state change of the read cavity, i.e., the amount of dispersion shift, so as to realize state reading of the qubit.

In the present embodiment, in the superconducting quantum chip design, the first target frequency of the qubit and the target coupling strength between the qubit and the target read cavity are included, and the second target frequency may be read directly from the superconducting quantum chip design scheme. Alternatively, based on the relationship of dispersion coupling between the qubit and the target read cavity, the second target frequency may also be calculated directly from the first target frequency.

Step 102, initializing a read coupling port configuration layout based on a configuration of the qubit, and a relative position of the qubit to the target read cavity.

In the present embodiment, the read coupling port configuration layout is used to represent a layout of a positional relationship between the qubit and a read coupling port of the target read cavity.

When designing the target read cavity, the target read cavity is generally realized using a coplanar waveguide with a standard impedance, in which an impedance of the target read cavity may be maintained as the standard impedance by reasonably designing a ratio of a width of a center conductor of the coplanar waveguide to a width of a grounded metal on either side of the center conductor in a layout of the target read cavity. In addition, for the read cavity with the standard impedance, a coupling mutual capacitance of the read cavity to the qubit is only related to a configuration of a neighboring coupling port. In this regard, it is possible to calculate the coupling strength between the qubit and the target read cavity only by the read coupling port configuration layout of the read cavity and the qubit without a complete layout of the read cavity, and the coupling strength is an unvalidated coupling strength, and a to-be-measured coupling strength.

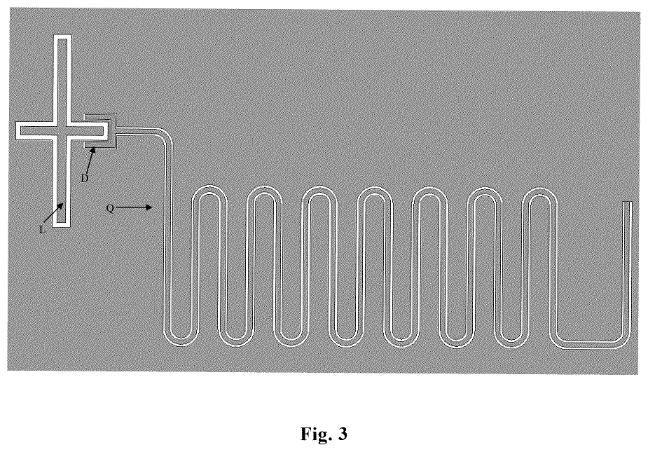

There are various configurations of the qubit in a superconducting quantum chip, and the various configurations include: a cross configuration, a symmetric asterisk configuration, a cross-like configuration, a coplanar parallel-plate configuration, etc. The cross configuration is obtained by connecting a cross capacitor to a superconducting Josephson junction. As shown in FIG. 2, a cross-shaped configuration is a qubit in the cross configuration, which is coupled to a control line (used to manipulate the qubit) at an upper end, and a left end of the qubit is used to set the superconducting Josephson junction, a right end of the qubit is coupled to a read cavity (also known as a read resonant cavity, which is used to read information of the qubit), and a lower end of the qubit may be coupled to a bus (which is used to realize interactions between different qubits). The symmetric asterisk configuration is a qubit consisting of a symmetric asterisk capacitor. The symmetric asterisk configuration is similar to a Chinese character “*”, in which an orthogonal cross and a diagonal cross have equal side lengths, thus the configuration is symmetric as a whole. The cross-like configuration is obtained based on a cross qubit with some structures being added, and the qubit in the cross-like configuration is designed for the application in which the superconducting qubit and a chip line distributed in different layers of the chip structure. A capacitor in the coplanar parallel-plate configuration consists of two coplanar parallel plates with the middle parts thereof are connected using a superconducting Josephson junction to form a qubit.

In the present embodiment, in the superconducting quantum chip design scheme, configuration requirements for the qubit and the positional relationship between the qubit and the target read cavity are included, the configuration of the qubit and the positional relationship between the qubit and the target read cavity may be read directly from the superconducting quantum chip, and based on the configuration of the qubit, a specific shape of the qubit may be determined; based on the positional relationship between the qubit and the target read cavity, a first positional relationship of read coupling ports between the qubit and the target read cavity may be determined, and the read coupling port configuration layout may be designed based on the shape of the qubit and the first positional relationship. For example, as shown in FIG. 2, the read coupling port configuration layout obtained by the initializing is a layout that uses a crossed-finger coupling configuration to enhance the coupling strength.

In the present embodiment, based on the configuration of the qubit and the positional relationship between the qubit and the target read cavity in the superconducting quantum chip design scheme, other configurations (e.g., a plug-in coupling configuration) may also be used to obtain the read coupling port configuration layout.

Step 103, calculating a to-be-measured coupling strength between the qubit and the read coupling port, based on the read coupling port configuration layout, the first target frequency, and the second target frequency.

In the present embodiment, the above step 103 includes: performing electromagnetic simulation on the read coupling port configuration layout to obtain the qubit self-capacitance of the qubit, a coupling mutual capacitance between the qubit and the read coupling port, and a port self-capacitance of the read coupling port; and taking the qubit self-capacitance, the coupling mutual capacitance, the port self-capacitance, the first target frequency, and the second target frequency into a formula of the to-be-measured coupling strength to obtain the to-be-measured coupling strength, where the formula of the to-be-measured coupling strength is used to represent a corresponding relationship of all five of the qubit self-capacitance, the coupling mutual capacitance, the port self-capacitance, the first target frequency, and the second target frequency with the to-be-measured coupling strength. In the present embodiment, the formula of the to-be-measured coupling strength is a conventional formula for calculating a coupling strength by using the self-capacitance, the coupling mutual capacitance, and the frequencies, as shown in equation (2), which will not be described in detail herein.

Step 104, in response to detecting that the to-be-measured coupling strength and the target coupling strength satisfy a preset condition, generating, based on the second target frequency and the read coupling port configuration layout, a complete layout including the qubit and the target read cavity.

In the present embodiment, since the target coupling strength may be a preset value, the preset condition is a condition set for the to-be-measured coupling strength and related to the target coupling strength. The preset condition is used to determine whether a preset relation is satisfied by the to-be-measured coupling strength and the target coupling strength, and the preset relation includes a variable of the target coupling strength. After obtaining the target coupling strength, the target coupling strength is first input into the preset relation to generate a target relation. For example, the target relation is that a difference between the to-be-measured coupling strength and the target coupling strength is less than or equal to a preset target value (the preset target value may be adjusted as required, for example, the preset target value is 0.1).

In the present embodiment, the to-be-measured coupling strength may be a coupling strength calculated by adjusting the read coupling port configuration layout in each iteration. For the to-be-measured coupling strength calculated for each adjustment of the read coupling port configuration layout, this to-be-measured coupling strength may be input into the target relation, to determine whether the target relation is established. If the target relation holds, it may be determined that the to-be-measured coupling strength obtained from this iteration and the target coupling strength satisfy the preset condition.

In the present embodiment, the generating, based on the second target frequency and the read coupling port configuration layout, a complete layout including the qubit and the target read cavity includes: completing the read coupling port based on the second target frequency, to generate the complete layout including the qubit and the target read cavity.

As shown in FIG. 3, a complete layout including a qubit L and a target read cavity Q after completing the read coupling port is shown, In FIG. 3, a gray shaded portion denotes a superconducting metal layer and a white portion denotes an etched portion of the metal layer. A cross metal layer structure on the left side is the cross configuration of the qubit L, and a curved snake structure on the right side is the configuration of the target read cavity Q. A crossed-finger portion, neighboring the target read cavity, of the qubit is a read coupling port D, and the remaining large shaded area on the outside is a grounded metal layer. There is an etched portion between the device and the grounded metal layer to form a self-capacitance of the device, and a coupling mutual capacitance is formed between the devices.

The method for coupling a superconducting qubit provided by embodiments of the present disclosure, when designing the read cavity, only focuses on the coupling port configuration layout of the read cavity and the qubit, greatly simplifying the layout design, simulation and iteration, accelerating the entire design and simulation flows of the read coupling port, which substantially reduces the number of iterations, efficiently realizes the target coupling strength between the qubit and the read cavity, and greatly improves a design efficiency of the read cavity.

In the method and apparatus for coupling a superconducting qubit provided by the embodiments of the present disclosure, first, a target coupling strength between a target read cavity and a qubit, a first target frequency of the qubit, and a second target frequency of the target read cavity are determined; secondly, a read coupling port configuration layout is initialized based on a configuration of the qubit, a relative position of the qubit to the target read cavity, the read coupling port configuration layout being used to represent a layout of a positional relationship between the qubit and a read coupling port of the target read cavity; then, a to-be-measured coupling strength between the qubit and the read coupling port is calculated based on the read coupling port configuration layout, the first target frequency, and the second target frequency; and finally, in response to detecting that the to-be-measured coupling strength and the target coupling strength satisfy a preset condition, a complete layout including the qubit and the target read cavity is generated based on the second target frequency and the read coupling port configuration layout. In the present disclosure, it is only required to focus on the read coupling port configuration layout reflecting the positional relationship between the qubit and the read coupling port, in order to calculate the to-be-measured coupling strength, and it is not necessary to completely design the layout of the entire read cavity, which greatly improves a design efficiency of the read cavity.

In an embodiment of the present disclosure, the method for coupling a superconducting qubit may further include: adjusting, in response to detecting that the to-be-measured coupling strength and the target coupling strength do not satisfy the preset condition, a spacing between the read coupling port and the qubit in the read coupling port configuration layout, to obtain a new read coupling port configuration layout; replacing the read coupling port configuration layout using the new read coupling port configuration layout; and continuing to calculate, based on the new read coupling port configuration layout, the first target frequency and the second target frequency, the to-be-measured coupling strength between the qubit and the read coupling port, until the to-be-measured coupling strength and the target coupling strength are detected to satisfy the preset condition.

In the present embodiment, the spacing between the read coupling port and the qubit refers to: an actual distance between the qubit and the coupling port. When the actual distance between the read coupling port and the qubit is large, the coupling strength between the two is small; when the actual distance between the read coupling port and the qubit is small, the coupling strength between the two is large.

In the present embodiment, after detecting that the to-be-measured coupling strength and the target coupling strength satisfy the preset condition, based on the second target frequency and the read coupling port configuration layout, the complete layout including the qubit and the target read cavity may be generated.

In the present embodiment, the read coupling port configuration layout may be a read coupling port obtained after multiple adjustments are made to specifications of the read coupling port in the layout or the spacing between the qubit and the read coupling port.

The method for coupling a superconducting qubit provided by the present embodiment, in response to detecting that the to-be-measured coupling strength and the target coupling strength do not satisfy the preset condition, adjusts the spacing between the read coupling port and the qubit in the read coupling port configuration layout to change the spacing between the read coupling port and the qubit, until the target read cavity that satisfies the second target frequency and the target coupling strength is obtained, simplifying the design and simulation of the layout, accelerating the design efficiency of the target read cavity, and providing another reliable implementation in which the to-be-measured coupling strength and the target coupling strength satisfy the preset condition.

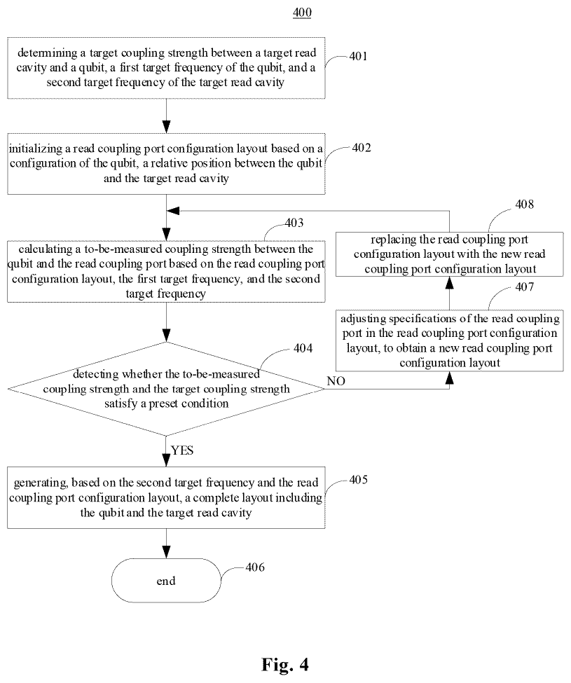

FIG. 4 shows a flow 400 of another embodiment of the method for coupling a superconducting qubit according to the present disclosure, and the method for coupling a superconducting qubit includes the following steps 401 to 408.

Step 401, determining a target coupling strength between a target read cavity and a qubit, a first target frequency of the qubit, and a second target frequency of the target read cavity, and then, performing step 402.

Step 402, initializing a read coupling port configuration layout based on a configuration of the qubit, a relative position between the qubit and the target read cavity, and then, performing step 403.

Step 403, calculating a to-be-measured coupling strength between the qubit and the read coupling port based on the read coupling port configuration layout, the first target frequency, and the second target frequency, and then, performing step 404.

Step 404, detecting whether the to-be-measured coupling strength and the target coupling strength satisfy a preset condition; if it is detected that the preset condition is satisfied, performing step 405; and if it is detected that the preset condition is not satisfied, performing step 407.

Step 405, generating, based on the second target frequency and the read coupling port configuration layout, a complete layout including the qubit and the target read cavity, and then, performing step 406.

It should be understood that the operations and features in the above step 401 to step 405 correspond to the operations and features in step 101 to step 104, respectively. Therefore, the above description for the operations and features in step 101 to step 104 applies to step 401 to step 405 as well, and detailed description thereof will be omitted herein.

Alternatively, for the embodiment shown in FIG. 4, the method for coupling a superconducting qubit provided by the present disclosure may further include: performing electromagnetic simulation on the complete layout to obtain a qubit self-capacitance of the qubit, and a coupling mutual capacitance between the qubit and the target read cavity; calculating a calculated coupling strength based on the qubit self-capacitance, the coupling mutual capacitance, the first target frequency, and the second target frequency; and determining, in response to detecting that the calculated coupling strength and the target coupling strength satisfy the preset condition, that the complete layout is correct.

Step 406, exiting.

Step 407, adjusting specifications of the read coupling port in the read coupling port configuration layout, to obtain a new read coupling port configuration layout, and then, performing step 408.

In the present embodiment, adjusting the specifications of the read coupling port may be adaptive adjusting based on a shape of the read coupling port. As shown in FIG. 2, the read coupling port has a finger-crossed shape, and the new read coupling port configuration layout may be obtained by adjusting a length a of a first finger portion of the read coupling port.

Step 408, replacing the read coupling port configuration layout with the new read coupling port configuration layout, and performing step 403.

The method for coupling a superconducting qubit provided by the present embodiment, in response to detecting that the to-be-measured coupling strength and the target coupling strength do not satisfy the preset condition, adjusts the specifications of the read coupling port in the read coupling port configuration layout to change the shape of the read coupling port, until the target read cavity that satisfies the second target frequency and the target coupling strength is obtained. With the method, it simplifies the design and simulation of the layout, accelerates the design efficiency of the target read cavity, and provides a reliable implementation in which the to-be-measured coupling strength and the target coupling strength satisfy the preset condition.

In the present embodiment, based on the configuration of the qubit and the read coupling port in the read coupling port configuration layout, lengths or widths of different areas of the read coupling port may be adjusted when adjusting the specifications of the read coupling port in the read coupling port configuration layout. In some alternative implementations of the present embodiment, the read coupling port includes a first coupling port with a crossed-finger shape, and the first coupling port includes: a first finger portion parallel to a length direction of a capacitance arm of the qubit, the capacitance arm being used for coupling to the read coupling port, and the adjusting, in response to detecting that the to-be-measured coupling strength and the target coupling strength do not satisfy the preset condition, specifications of the read coupling port in the read coupling port configuration layout, to obtain a new read coupling port configuration layout includes:
decreasing, in response to the to-be-measured coupling strength being greater than the target coupling strength by a preset strength value, a length of the first finger portion by a first preset value, to obtain the new read coupling port configuration layout; and increasing, in response to the target coupling strength being greater than the to-be-measured coupling strength by the preset strength value, the length of the first finger portion by the first preset value, to obtain the new read coupling port configuration layout.

As shown in FIG. 3, the read coupling port is a crossed-finger first coupling port, the first coupling port includes a first finger portion, and a length of the first finger portion is a. Further, in FIG. 3, the first coupling port may also include: a second finger portion parallel to a width direction of the capacitance arm of the qubit, and a width of the second finger portion is b. By adjusting the width of the second finger portion, a new read coupling port configuration may also be obtained.

In this alternative implementation, based on a comparison of the to-be-measured coupling strength with the target coupling strength, iteration on the read coupling port configuration layout is performed.

In this alternative implementation, the first preset value, the preset strength value may be set based on a design accuracy. For example, the preset strength value is 10% and the first preset value is 10 um.

In the method for adjusting the specifications of the read coupling port provided by this alternative implementation, in the case where the read coupling port is of the crossed-finger configuration and the read coupling port is coupled to the capacitance arm of the qubit, by adjusting the first finger portion in the read coupling port that is parallel to the length direction of the capacitance arm of the qubit, it may quickly and conveniently bring the obtained new coupling port close to the second target frequency, ensuring an efficiency of adjusting the read coupling port configuration layout.

In some alternative implementations of the present embodiment, the read coupling port includes a second coupling port with a crossed-finger shape, and the second coupling port includes: a second finger portion parallel to a width direction of a capacitance arm of the qubit, the capacitance arm being used for coupling to the read coupling port, and the adjusting, in response to detecting that the to-be-measured coupling strength and the target coupling strength do not satisfy the preset condition, specifications of the read coupling port in the read coupling port configuration layout, to obtain a new read coupling port configuration layout includes: decreasing, in response to the to-be-measured coupling strength being greater than the target coupling strength by a preset strength value, a width of the second finger portion by a second preset value, to obtain the new read coupling port configuration layout; and increasing, in response to the target coupling strength being greater than the to-be-measured coupling strength by the preset strength value, the width of the second finger portion by the second preset value, to obtain the new read coupling port configuration layout. In the present embodiment, the second preset value is independent of the preset strength value.

In the method for adjusting the specifications of the read coupling port provided by this alternative implementation, in the case where the read coupling port is of the crossed-finger configuration and the read coupling port is coupled to the capacitance arm of the qubit, by adjusting the second finger portion in the read coupling port that is parallel to the width direction of the capacitance arm of the qubit, it may quickly and conveniently bring the obtained new coupling port close to the second target frequency, ensuring the efficiency of adjusting the read coupling port configuration layout.

For the above embodiment, in order to validate the reliability of the generated complete layout, in another embodiment of the present disclosure, the method for coupling a superconducting qubit may further include: performing electromagnetic simulation on the complete layout to obtain a qubit self-capacitance of the qubit, and a coupling mutual capacitance between the qubit and the target read cavity; calculating a calculated coupling strength based on the qubit self-capacitance, the coupling mutual capacitance, the first target frequency, and the second target frequency; and determining, in response to detecting that the calculated coupling strength and the target coupling strength satisfy the preset condition, that the complete layout is correct.

Alternatively, in response to detecting that the calculated coupling strength and the target coupling strength do not satisfy the preset condition, adjusting a spacing between the qubit and the read coupling port in the read coupling port configuration layout, to obtain a new read coupling port configuration layout; and calculating the to-be-measured coupling strength based on the new read coupling port configuration layout, and in response to the to-be-measured coupling strength and the target coupling strength satisfying the preset condition, generating a new complete layout.

Alternatively, in response to detecting that the calculated coupling strength and the target coupling strength do not satisfy the preset condition, adjusting specifications of the read coupling port in the read coupling port configuration layout, to obtain a new read coupling port configuration layout; and calculating the to-be-measured coupling strength based on the new read coupling port configuration layout, and in response to the to-be-measured coupling strength and the target coupling strength satisfying the preset condition, generating a new complete layout.

In the present embodiment, the calculating the to-be-measured coupling strength based on the new read coupling port configuration layout includes: inputting the new read coupling port configuration layout, dimension parameters of the qubit and the read coupling port into a simulation software, to obtain a simulation capacitance and a simulation frequency; and calculating the to-be-measured coupling strength based on the simulation capacitance and the simulation frequency.

In the method for coupling a superconducting qubit provided by the present embodiment, electromagnetic simulation is performed on the complete layout, the calculated coupling strength is calculated, and in response to the calculated coupling strength and the target coupling strength satisfying the preset condition, it is determined that the complete layout is correct. The complete layout may be applied to the actual production of quantum chips, which improves the reliability of obtaining the target read cavity.

In some alternative implementations of the present embodiment, the calculating a calculated coupling strength based on the qubit self-capacitance, the coupling mutual capacitance, the first target frequency, and the second target frequency, includes:
taking the qubit self-capacitance, the coupling mutual capacitance, the first target frequency, and the second target frequency into a read cavity impedance coupling relation to obtain the calculated coupling strength, where the read cavity impedance coupling relation is used to represent a corresponding relationship between all five of the coupling mutual capacitance, the qubit self-capacitance, a standard impedance, the first target frequency, and the second target frequency, and the calculated coupling strength.

By modeling the chip layout using an equivalent circuit, the coupling strength between the qubit and the read cavity may be as shown in equation (2):

$$g = \frac{1}{2} \frac{{C}_{qr}}{\sqrt{{C}_{q} {C}_{r}}} \sqrt{{ω}_{q} {ω}_{r}} \qquad ( 2 )$$

In Equation (2), C_{q} and Cᵣ are a self-capacitance of the qubit and the self-capacitance of the read cavity, respectively, C_{qr} is the coupling mutual capacitance between the qubit and the read cavity, and ω_{q} and ωᵣ are the frequency of the qubit and the frequency of the read cavity, respectively. After completing the design of a preliminary version of the complete layout including the qubit and the read cavity layout, electromagnetic simulation may be performed on the layout of the quantum chip to obtain the self-capacitances, the mutual capacitance, and the frequency information of the qubit and the read cavity, and the coupling strength between the qubit and the read cavity may be calculated by taking the same into the above equation (2).

The read cavity is usually embodied using a quarter coplanar waveguide having a 50-ohm standard impedance (Z₀), i.e.,

$${Z}_{r} = \frac{1}{{C}_{r} {ω}_{r}} = {Z}_{0} \qquad ( 3 )$$

In equation (3), Zr is the impedance of the read cavity, and Z₀=50 ohm is the standard impedance. By taking this equation into Equation (2), to obtain:

$$g = \frac{1}{2} \frac{{C}_{qr}}{\sqrt{{C}_{q} {C}_{r}}} \sqrt{{ω}_{q} {ω}_{r}} \qquad ( 4 )$$

In Equation (4), the read cavity impedance Zr is replaced with the standard 50-ohm impedance Z₀. From the above Equation (4), it can be seen that the read coupling strength is no longer explicitly related to the self-capacitance Cr of the read cavity. In fact, the impedance of the read cavity may be kept uniformly at 50-ohm by reasonably designing a ratio of the width of the center conductor of the coplanar waveguide to the width of either side of the grounded metal. In addition, the coupling mutual capacitance between the read cavity and the qubit is only related to a configuration of a neighboring coupling port. Therefore, there is no need for a complete read cavity layout, but only the coupling port configuration layout (as shown in FIG. 2) between the read cavity and the qubit is required. Simulation may be performed on the coupling port configuration layout to obtain the coupling capacitance C_{qr} and the qubit self-capacitance C_{q}. Then the first target frequency of the qubit and the second target frequency of the read cavity which are set in advance are added, the coupling strength between the qubit and the read cavity may be calculated by using equation (4).

In the present embodiment, the read cavity impedance coupling equation may be calculated using the equation shown in equation (4) (where the read cavity corresponding to equation (4) is the target read cavity), to obtain the calculated coupling strength corresponding to the coupling strength between the qubit and the read cavity.

The present embodiment provides the method for obtaining the calculated coupling strength, in which, when the impedance of the target read cavity is the standard ohm impedance, and the target read cavity is directly coupled to the qubit to form a dispersion coupling relationship (the frequency difference between the qubit and the target read cavity is much larger than the coupling strength between them), the calculated coupling strength between the qubit and the target read cavity can be calculated by using the read cavity impedance coupling equation. A reliable calculation method is provided for the calculation of the calculated coupling strength.

In some alternative implementations of the present embodiment, the determining a target coupling strength between a target read cavity and a qubit, a first target frequency of the qubit, and a second target frequency of the target read cavity includes: acquiring a preset first target frequency of the qubit and the target coupling strength; and calculating the second target frequency based on the first target frequency and the target coupling strength.

In the present embodiment, the second target frequency may be a value, and the calculating the second target frequency based on the first target frequency and the target coupling strength includes: determining a first magnitude of the target coupling strength and a set fixed frequency, based on a principle of dispersion coupling condition, where a magnitude of the set fixed frequency is greater than the magnitude of the target coupling strength; and increasing the first target frequency by the set fixed frequency to obtain the second target frequency.

For example, in a specific example, if the first magnitude is MHz, the magnitude of the set fixed frequency is GHz, and the set fixed frequency may be a value greater than 1 GHz.

Alternatively, the second target frequency may have multiple values, and the calculating the second target frequency based on the first target frequency and the target coupling strength includes: determining a first magnitude of the target coupling strength and a frequency increment based on a principle of dispersion coupling condition, where the frequency increment is of the same magnitude as the first magnitude, and a value of the frequency increment is greater than the target coupling strength; and subtracting a set frequency value from the first target frequency to obtain a base frequency, and sequentially increasing the base frequency by the frequency increment for a set number of times, where each time the base frequency is increased by the frequency increment, a target frequency is obtained, and a final value obtained by increasing the base frequency by the set number of frequency increments is less than the magnitude of the first target frequency.

In the present embodiment, when the frequency difference between the qubit and the target read cavity is much larger than the coupling strength between the two, the target coupling strength may be obtained by accurately designing the coupling port between the read cavity and the qubit, and based on the first target frequency and the target coupling strength, the second target frequencies may be calculated, providing a reliable implementation for obtaining the second target frequencies.

In some alternative implementations of the present embodiment, it is possible to provide multiple second target frequencies, and the initializing a read coupling port configuration layout based on a configuration of the qubit and a relative position of the qubit to the target read cavity, includes: determining multiple read coupling ports based on the multiple second target frequencies; initializing the read coupling port configuration layout corresponding to the multiple read coupling ports, based on the configuration of the qubit and the relative positions of the qubit to respective target read cavities at the multiple second target frequencies; and the calculating a to-be-measured coupling strength between the qubit and the read coupling port, based on the read coupling port configuration layout, the first target frequency, and the second target frequency includes: obtaining an intermediate frequency based on the multiple second target frequencies; and calculating the to-be-measured coupling strength between the qubit and a read coupling port, based on the read coupling port configuration layout corresponding to the multiple read coupling ports, the first target frequency, and the intermediate frequency.

In this alternative implementation, the obtaining an intermediate frequency based on the multiple second target frequencies includes: averaging the multiple second target frequencies to obtain the intermediate frequency.

Then, the calculating a to-be-measured coupling strength between the qubit and the read coupling port, based on the read coupling port configuration layout, the first target frequency, and the second target frequency includes: using the intermediate frequency as the second target frequency, and calculating the to-be-measured coupling strength between the qubit and the read coupling port, based on the read coupling port configuration layouts each corresponding to a read coupling port of the multiple read coupling ports, the first target frequency, and the second target frequency, where the to-be-measured coupling strength in the present embodiment may be used as a coupling strength of a read coupling port configuration layout between each read coupling port in the multiple read coupling ports and the qubit.

In the present embodiment, for a second target frequency of a read cavity in the multiple second target frequency, in response to detecting that the to-be-measured coupling strength and the target coupling strength satisfy the preset condition, based on the second target frequency and the read coupling port configuration layout, the complete layout including the qubit and the target read cavity may be generated.

In the method for initializing a read coupling port configuration layout provided in the present embodiment, multiple read coupling port configuration layouts at the multiple second target frequencies are simultaneously generated, providing a reliable implementation basis for simultaneously generating multiple target read cavities. For a superconducting quantum chip containing multiple sets of different read cavities, the scheme of the present disclosure design the read coupling ports only once, to accomplish multiple sets of different read cavities.

In order to validate an effect of the scheme of the present disclosure, the read cavity coupling port design scheme proposed in the present disclosure is applied to a layout design of a superconducting quantum chip containing 6 sets of read cavities. With the flow framework proposed in the scheme of the present disclosure, a read cavity layout satisfying requirements and with an efficient iteration is accurately designed to validate the effectiveness and advantages of the scheme of the present disclosure in the following steps.

First step: determining target frequencies of the read cavities and a target coupling strength.

In the design scheme of this superconducting quantum chip, the frequency of the qubit is set to 6.5 GHz, and under the premise of satisfying dispersion coupling, the target frequencies of the 6 sets of read cavities are determined as 4.86, 4.94, 5.02, 5.10, 5.18, and 5.26 GHz (a frequency interval being 80 MHz). The target coupling strength between a read cavity and the qubit is set to 38 MHz.

Second step: initializing a read coupling port layout.

Based on the layout of the qubit and a relative position of a read cavity to the qubit, a preliminary read coupling port configuration layout may be designed. Considering that the frequency difference between each two read cavities of the 6 sets of is not too large, the 6 sets of read coupling ports adopt an identical crossed-finger coupling configuration (FIG. 2), which can meet the design requirements.

Third step and fourth step: performing iterations on the read coupling port layout, performing simulation, and calculating a coupling strength.

After several iterations in the third and fourth steps, electromagnetic simulation may be performed on a final version of a read coupling port configuration layout to obtain the qubit self-capacitance C_{q}=65 fF, and the coupling mutual capacitance between the qubit and a read cavity C_{qr}=2.72 fF. The qubit frequency ω_{q}=6.5 GHz, the read cavity frequency ωᵣ takes the intermediate frequency GHz, and brought into Eq. (4) to calculate the coupling strength g=38.1 MHz between the qubit and a read cavity, which is very close to the target coupling strength and meets the requirement.

Fifth step: validating a complete layout.

Based on the target frequency of the read cavity, the designed read coupling port is completed to form a complete layout of the qubit and the read cavity, and a schematic diagram is as shown in FIG. 3. Electromagnetic simulation is performed on the complete layout, and based on simulation data, the coupling strength between the qubit and the read cavity is cross-validated using various methods, results are as shown in Table 1.

TABLE 1

| | | Coupling strength between qubit and read | | |
|---|---|---|---|---|
| | Read cavity | cavity (MHz) | | |
| | frequency | Resonance | Equivalent | iEPR |
| Layout | (GHz) | sweep | circuit | method |
| Layout1 | 5.02, 5.10 | 38.4 | 37.7 | 38.5 |
| Layout2 | 5.18, 5.26 | 36.1 | 33.4 | 37.3 |
| Layout3 | 5.02, 5.10 | 38.4 | 37.7 | 35.5 |

In Table 1, Layout 1, 2, and 3 are three sets of qubit configurations, and their corresponding read cavity frequencies are as shown in Table 1. The coupling strength between the qubit and the read cavity is cross-validated using three different simulation validation methods: resonance sweep, equivalent circuit, and iEPR (inductance energy participation ratio) method. Here, the resonance sweep method tunes the qubit frequency to resonate at the read cavity frequency, and uses the frequency difference between the two devices to calculate the coupling strength; the equivalent circuit method uses the self-capacitance and the mutual capacitance information of the devices to model an equivalent circuit and uses the previously mentioned equation (1) to calculate the coupling strength; and the iEPR method uses an electromagnetic field distribution around the devices to calculate the coupling strength between the devices. The principles of the three methods are different, but their calculation results of the coupling strength between the qubit and the read cavity under the complete layout are all very close to the target coupling strength of 38 MHz, thus validating the effectiveness of the scheme of the present disclosure.

The layout design of a superconducting quantum chip containing 6 sets of read cavities has been accomplished by applying the scheme of the present disclosure. After simulation and validation, the coupling strength between the qubit and each read cavity meets the design requirements. Therefore, the scheme of the present disclosure can improve a design efficiency of the superconducting quantum chip, and is of guiding significance for the design, simulation, and iteration of the superconducting quantum chip.

In some alternative implementations of the present embodiment, the calculating a to-be-measured coupling strength between the qubit and the read coupling port based on the read coupling port configuration layout, the first target frequency, and the second target frequency includes:
performing electromagnetic simulation on the read coupling port configuration layout to obtain the qubit self-capacitance of the qubit, and a port mutual capacitance between the qubit and the read coupling port; and
taking the qubit self-capacitance, the port mutual capacitance, the first target frequency, and the second target frequency into a port impedance coupling equation to obtain the to-be-measured coupling strength,
where the port impedance coupling equation is used to represent a corresponding relationship between all five of the port mutual capacitance, the qubit self-capacitance, the standard impedance, the first target frequency, and the second target frequency, and the to-be-measured coupling strength.

In this alternative implementation, the port impedance coupling equation may calculate using the equation as shown in Eq. (4) (where the read cavity corresponding to Eq. (4) is the read coupling port), to obtain the to-be-measured coupling strength corresponding to the coupling strength between the qubit and the read cavity.

In the method for coupling a superconducting qubit provided by the present embodiment, electromagnetic simulation is performed on the read coupling port configuration layout, the to-be-measured coupling strength is calculated, and in response to the to-be-measured coupling strength and the target coupling strength satisfying the preset condition, it is determined that the read coupling port and the qubit have correct configurations, improving the reliability of obtaining the target read cavity.

In some alternative implementations of the present embodiment, in response to detecting that the to-be-measured coupling strength and the target coupling strength satisfy a preset condition, generating, based on the second target frequency and the read coupling port configuration layout, a complete layout including the qubit and the target read cavity includes:
completing, in response to detecting that the to-be-measured coupling strength and the target coupling strength satisfy the preset condition, the read coupling port in the read coupling port configuration layout, and generating the complete layout including the qubit and the target read cavity.

In the present embodiment, based on the positional relationship between the qubit and the target read cavity in the complete layout, the read coupling port may be completed, so that the completed read coupling port forms the target read cavity. It should be noted that the target read cavity is usually realized using a one-quarter coplanar waveguide with standard impedance. In order to ensure the effectiveness of the generation of the target read cavity, the ratio of the width of the center conductor of the coplanar waveguide to the width of the grounded metal on either side needs to be reasonably designed. For example, the target read cavity is a 50-ohm coplanar waveguide. When completing the read coupling port, it is necessary to ensure that the ratio of the width of the center conductor of the coplanar waveguide to the width of either side of the grounded metal is 2/1.

The present embodiment provides the generation of a complete layout including the qubit and the target read cavity, in which it is only required to focus on the read coupling port configuration layout of the target read cavity and the qubit, accelerating the entire design and simulation flows of the read coupling port. In the generation of the target read cavity, only the read coupling port needs to be completed, simplifying the simulation flow of the target read cavity, and improving the design efficiency of the target read cavity.

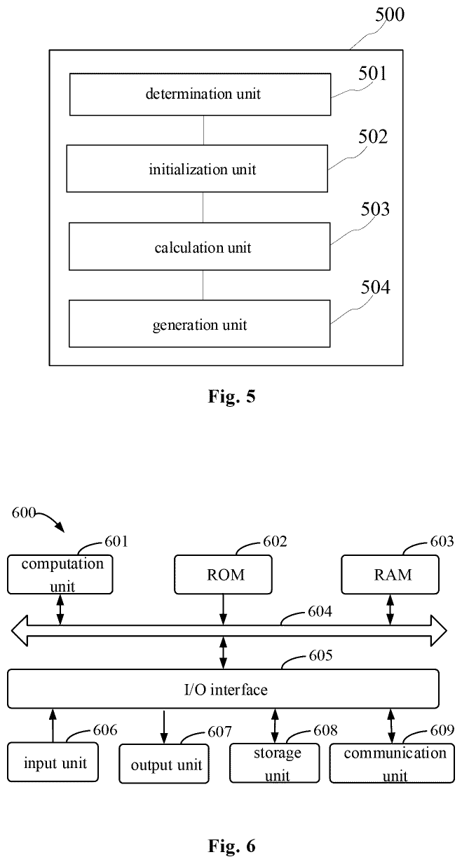

With further reference to FIG. 5, as an implementation of the method shown in the above figures, the present disclosure provides an embodiment of an apparatus for coupling a superconducting qubit, the embodiment of the apparatus corresponds to the embodiment of the method shown in FIG. 1, and the apparatus may be applied in various electronic devices.

As shown in FIG. 5, the apparatus 500 for coupling a superconducting qubit provided in the present embodiment includes: a determination unit 501, an initialization unit 502, a calculation unit 503, and a generation unit 504. The determination unit 501 may be configured to determine a target coupling strength between a target read cavity and a qubit, a first target frequency of the qubit, and a second target frequency of the target read cavity. The initialization unit 502 may be configured to initialize a read coupling port configuration layout based on a configuration of the qubit, a relative position of the qubit to the target read cavity, the read coupling port configuration layout being used to represent a layout of a positional relationship between the qubit and a read coupling port of the target read cavity. The calculation unit 503 may be configured to calculate a to-be-measured coupling strength between the qubit and the read coupling port, based on the read coupling port configuration layout, the first target frequency, and the second target frequency. The generation unit 504 may be configured to, in response to detecting that the to-be-measured coupling strength and the target coupling strength satisfy a preset condition, generate, based on the second target frequency and the read coupling port configuration layout, a complete layout comprising the qubit and the target read cavity.

In the present embodiment, in the apparatus 500 for coupling a superconducting qubit, for the specific processing and the technical effects of the determination unit 501, the initialization unit 502, the calculation unit 503 and the generation unit 504, reference may be made to the relevant descriptions of the step 101, step 102, step 103 and step 104 in the corresponding embodiment of FIG. 1 respectively, and detailed description thereof will be omitted.

In some alternative implementations of the present embodiment, the apparatus further includes: a spacing adjusting unit (not shown in the figure), and the spacing adjusting unit is configured to adjust, in response to detecting that the to-be-measured coupling strength and the target coupling strength do not satisfy the preset condition, a spacing between the read coupling port and the qubit in the read coupling port configuration layout, to obtain a new read coupling port configuration layout; replace the read coupling port configuration layout with the new read coupling port configuration layout; and continue to control the calculation unit 503 to work, until the to-be-measured coupling strength and the target coupling strength are detected to satisfy the preset condition, and control the generation unit 504 to work.

In some alternative implementations of the present embodiment, the apparatus further includes: a specification adjusting unit (not shown in the figure), and the specification adjusting unit may be configured to adjust, in response to detecting that the to-be-measured coupling strength and the target coupling strength do not satisfy the preset condition, specifications of the read coupling port in the read coupling port configuration layout, to obtain a new read coupling port configuration layout; replace the read coupling port configuration layout with the new read coupling port configuration layout; and continue to control the calculation unit 503 to work, until the to-be-measured coupling strength and the target coupling strength are detected to satisfy the preset condition, and control the generation unit 504 to work.

In some alternative implementations of the present embodiment, the read coupling port includes: a crossed-finger first coupling port, and the first coupling port includes: a first coupling port of a crossed-finger shape, the first coupling port comprising a first finger portion parallel to a length direction of a capacitance arm of the qubit and the capacitance arm being used for coupling to the read coupling port, and the specification adjusting unit is further configured to: decrease, in response to the to-be-measured coupling strength being greater than the target coupling strength by a preset strength value, a length of the first finger portion by a first preset value, to obtain the new read coupling port configuration layout; and increase, in response to the target coupling strength being greater than the to-be-measured coupling strength by the preset strength value, the length of the first finger portion by the first preset value, to obtain the new read coupling port configuration layout.

In some alternative implementations of the present embodiment, the read coupling port includes: a second coupling port of a crossed-finger shape, the second coupling port comprising a second finger portion parallel to a width direction of a capacitance arm of the qubit and the capacitance arm being used for coupling to the read coupling port, and the specification adjusting unit is further configured to: decrease, in response to the to-be-measured coupling strength being greater than the target coupling strength by a preset strength value, a width of the second finger portion by a second preset value, to obtain the new read coupling port configuration layout; and increase, in response to the target coupling strength being greater than the to-be-measured coupling strength by the preset strength value, the width of the second finger portion by the second preset value, to obtain the new read coupling port configuration layout.

In some alternative implementations of the present embodiment, the apparatus further includes: a validating unit (not shown in the figure). The verification unit may be configured to perform electromagnetic simulation on the complete layout to obtain a qubit self-capacitance of the qubit, and a coupling mutual capacitance between the qubit and the target read cavity; calculate a calculated coupling strength based on the qubit self-capacitance, the coupling mutual capacitance, the first target frequency, and the second target frequency; and determine, in response to detecting that the calculated coupling strength and the target coupling strength satisfy the preset condition, that the complete layout is correct.

In some alternative implementations of the present embodiment, the validating is further configured to: take the qubit self-capacitance, the coupling mutual capacitance, the first target frequency, and the second target frequency into a read cavity impedance coupling equation to obtain the calculated coupling strength, where the read cavity impedance coupling equation is used to represent a corresponding relationship between all five of the coupling mutual capacitance, the qubit self-capacitance, a standard impedance, the first target frequency, and the second target frequency, and the calculated coupling strength.

In some alternative implementations of the present embodiment, the determination unit 501 is further configured to: acquire a preset first target frequency of the qubit and the target coupling strength; and calculate the second target frequency based on the first target frequency and the target coupling strength.

In some alternative implementations of the present embodiment, a plurality of second target frequencies are provided, and the initialization unit 502 is further configured to: determine a plurality of read coupling ports based on the a plurality of second target frequencies; initialize the read coupling port configuration layout corresponding to the plurality of read coupling ports, based on the configuration of the qubit and relative positions of the qubit to respective target read cavities at the plurality of second target frequencies; and the calculation unit 503 is further configured to: obtain an intermediate frequency based on the plurality of second target frequencies; and calculate a to-be-measured coupling strength between the qubit and a read coupling port, based on the read coupling port configuration layout corresponding to the plurality of read coupling ports, the first target frequency, and the intermediate frequency.

In some alternative implementations of the present embodiment, the calculation unit 503 is further configured to: perform electromagnetic simulation on the read coupling port configuration layout to obtain the qubit self-capacitance of the qubit, and a port mutual capacitance between the qubit and the read coupling port; and take the qubit self-capacitance, the port mutual capacitance, the first target frequency, and the second target frequency into a port impedance coupling equation to obtain the to-be-measured coupling strength, where the port impedance coupling equation is used to represent a corresponding relationship between all five of the port mutual capacitance, the qubit self-capacitance, the standard impedance, the first target frequency, and the second target frequency, and the to-be-measured coupling strength.

In some alternative implementations of the present embodiment, the generation unit 504 is further configured to: complete, in response to detecting that the to-be-measured coupling strength and the target coupling strength satisfy the preset condition, the read coupling port in the read coupling port configuration layout, and generate the complete layout including the qubit and the target read cavity.

In the apparatus for coupling a superconducting qubit provided by an embodiment of the present disclosure, first, the determination unit 501 determines a target coupling strength between a target read cavity and a qubit, a first target frequency of the qubit, and a second target frequency of the target read cavity; secondly, the initialization unit 502 initializes a read coupling port configuration layout based on a configuration of the qubit, a relative position of the qubit to the target read cavity, the read coupling port configuration layout being used to represent a layout of a positional relationship between the qubit and a read coupling port of the target read cavity; then, the calculation unit 503 calculates to obtain a to-be-measured coupling strength between the qubit and the read coupling port, based on the read coupling port configuration layout, the first target frequency, and the second target frequency; and finally, the generation unit 504 generates, in response to detecting that the to-be-measured coupling strength and the target coupling strength satisfy a preset condition, based on the second target frequency and the read coupling port configuration layout, a complete layout including the qubit and the target read cavity. The present disclosure only needs to focus on the read coupling port configuration layout reflecting the positional relationship between the qubit and the read coupling port, in order to calculate the to-be-measured coupling strength, and it is not necessary to completely design the layout of the entire read cavity, which greatly improves a design efficiency of the read cavity.

According to an embodiment of the present disclosure, the present disclosure also provides an electronic device, a readable storage medium, and a computer program product.

FIG. 6 illustrates a schematic block diagram of an example electronic device 600 for implementing the embodiments of the present disclosure. The electronic device is intended to represent various forms of digital computers, such as laptop computers, desktop computers, workbenches, personal digital assistants, servers, blade servers, mainframe computers, and other suitable computers. The electronic device may also represent various forms of mobile apparatuses, such as personal digital processors, cellular phones, smart phones, wearable devices, and other similar computing apparatuses. The components shown herein, their connections and relationships, and their functions are merely examples, and are not intended to limit the implementation of the present disclosure described and/or claimed herein.

As shown in FIG. 6, the device 600 includes a computation unit 601, which may perform various appropriate actions and processing, based on a computer program stored in a read-only memory (ROM) 602 or a computer program loaded from a storage unit 608 into a random access memory (RAM) 603. In the RAM 603, various programs and data required for the operation of the device 600 may also be stored. The computation unit 601, the ROM 602, and the RAM 603 are connected to each other through a bus 604. An input/output (I/O) interface 605 is also connected to the bus 604.

A plurality of components in the device 600 are connected to the I/O interface 605, including: an input unit 606, for example, a keyboard and a mouse; an output unit 607, for example, various types of displays and speakers; the storage unit 608, for example, a disk and an optical disk; and a communication unit 609, for example, a network card, a modem, or a wireless communication transceiver. The communication unit 609 allows the device 600 to exchange information/data with other devices over a computer network such as the Internet and/or various telecommunication networks.

The computation unit 601 may be various general-purpose and/or dedicated processing components having processing and computing capabilities. Some examples of the computation unit 601 include, but are not limited to, central processing unit (CPU), graphics processing unit (GPU), various dedicated artificial intelligence (AI) computing chips, various computing units running machine learning model algorithms, digital signal processors (DSP), and any appropriate processors, controllers, microcontrollers, etc. The computation unit 601 performs the various methods and processes described above, such as a method for coupling a superconducting qubit. For example, in some embodiments, a method for coupling a superconducting qubit may be implemented as a computer software program, which is tangibly included in a machine readable medium, such as the storage unit 608. In some embodiments, part or all of the computer program may be loaded and/or installed on the device 600 via the ROM 602 and/or the communication unit 609. When the computer program is loaded into the RAM 603 and executed by the computation unit 601, one or more steps of a method for coupling a superconducting qubit described above may be performed. Alternatively, in other embodiments, the computation unit 601 may be configured to perform a method for coupling a superconducting qubit by any other appropriate means (for example, by means of firmware).

In the technical solution of the present disclosure, the acquisition, storage, and application of the user personal information involved are all in compliance with the relevant laws and regulations, and do not violate public order and good customs.

What is claimed is:

1. A method for coupling a superconducting qubit, the method comprising:
determining a target coupling strength between a target read cavity and a qubit, a first target frequency of the qubit, and a second target frequency of the target read cavity;
initializing a read coupling port configuration layout based on a configuration of the qubit, a relative position of the qubit to the target read cavity, the read coupling port configuration layout being used to represent a layout of a positional relationship between the qubit and a read coupling port of the target read cavity;
calculating a to-be-measured coupling strength between the qubit and the read coupling port, based on the read coupling port configuration layout, the first target frequency, and the second target frequency; and
in response to detecting that the to-be-measured coupling strength and the target coupling strength satisfy a preset condition, generating, based on the second target frequency and the read coupling port configuration layout, a complete layout comprising the qubit and the target read cavity.

2. The method according to claim 1, wherein the method further comprises:
adjusting, in response to detecting that the to-be-measured coupling strength and the target coupling strength do not satisfy the preset condition, a spacing between the read coupling port and the qubit in the read coupling port configuration layout, to obtain a new read coupling port configuration layout;
replacing the read coupling port configuration layout with the new read coupling port configuration layout; and
continuing to calculate, based on the new read coupling port configuration layout, the first target frequency and the second target frequency, the to-be-measured coupling strength between the qubit and the read coupling port, until the to-be-measured coupling strength and the target coupling strength are detected to satisfy the preset condition.

3. The method according to claim 1, wherein the method further comprises:
adjusting, in response to detecting that the to-be-measured coupling strength and the target coupling strength do not satisfy the preset condition, specifications of the read coupling port in the read coupling port configuration layout, to obtain a new read coupling port configuration layout;
replacing the read coupling port configuration layout with the new read coupling port configuration layout; and
continuing to calculate, based on the new read coupling port configuration layout, the first target frequency and the second target frequency, the to-be-measured coupling strength between the qubit and the read coupling port, until the to-be-measured coupling strength and the target coupling strength are detected to satisfy the preset condition.

4. The method according to claim 3, wherein the read coupling port comprises: a first coupling port of a crossed-finger shape, the first coupling port comprising a first finger portion parallel to a length direction of a capacitance arm of the qubit and the capacitance arm being used for coupling to the read coupling port, and the adjusting, in response to detecting that the to-be-measured coupling strength and the target coupling strength do not satisfy the preset condition, specifications of the read coupling port in the read coupling port configuration layout, to obtain a new read coupling port configuration layout comprises:
decreasing, in response to the to-be-measured coupling strength being greater than the target coupling strength by a preset strength value, a length of the first finger portion by a first preset value, to obtain the new read coupling port configuration layout; and
increasing, in response to the target coupling strength being greater than the to-be-measured coupling strength by the preset strength value, the length of the first finger portion by the first preset value, to obtain the new read coupling port configuration layout.

5. The method according to claim 3, wherein the read coupling port comprises: a second coupling port of a crossed-finger shape, the second coupling port comprising a second finger portion parallel to a width direction of a capacitance arm of the qubit and the capacitance arm being used for coupling to the read coupling port, and the adjusting, in response to detecting that the to-be-measured coupling strength and the target coupling strength do not satisfy the preset condition, specifications of the read coupling port in the read coupling port configuration layout, to obtain a new read coupling port configuration layout comprises:
decreasing, in response to the to-be-measured coupling strength being greater than the target coupling strength by a preset strength value, a width of the second finger portion by a second preset value, to obtain the new read coupling port configuration layout; and
increasing, in response to the target coupling strength being greater than the to-be-measured coupling strength by the preset strength value, the width of the second finger portion by the second preset value, to obtain the new read coupling port configuration layout.

6. The method according to claim 1, wherein the method further comprises:
performing electromagnetic simulation on the complete layout to obtain a qubit self-capacitance of the qubit, and a coupling mutual capacitance between the qubit and the target read cavity;
calculating a calculated coupling strength based on the qubit self-capacitance, the coupling mutual capacitance, the first target frequency, and the second target frequency; and
determining, in response to detecting that the calculated coupling strength and the target coupling strength satisfy the preset condition, that the complete layout is correct.

7. The method according to claim 6, wherein the calculating a calculated coupling strength based on the qubit self-capacitance, the coupling mutual capacitance, the first target frequency, and the second target frequency comprises:
taking the qubit self-capacitance, the coupling mutual capacitance, the first target frequency, and the second target frequency into a read cavity impedance coupling equation to obtain the calculated coupling strength,
wherein the read cavity impedance coupling equation is used to represent a corresponding relationship between all five of the coupling mutual capacitance, the qubit self-capacitance, a standard impedance, the first target frequency, and the second target frequency, and the calculated coupling strength.

8. The method according to claim 1, wherein the determining a target coupling strength between a target read cavity and a qubit, a first target frequency of the qubit, and a second target frequency of the target read cavity comprises:
acquiring a preset first target frequency of the qubit and the target coupling strength; and
calculating the second target frequency based on the first target frequency and the target coupling strength.

9. The method according to claim 1, wherein a plurality of second target frequencies are provided, and the initializing a read coupling port configuration layout based on a configuration of the qubit and a relative position of the qubit to the target read cavity comprises:
determining a plurality of read coupling ports based on a plurality of second target frequencies;
initializing the read coupling port configuration layouts corresponding to the plurality of read coupling ports, based on the configuration of the qubit and relative positions of the qubit to respective target read cavities at the plurality of second target frequencies; and
the calculating a to-be-measured coupling strength between the qubit and the read coupling port, based on the read coupling port configuration layout, the first target frequency, and the second target frequency comprises:
obtaining an intermediate frequency based on the plurality of second target frequencies; and calculating a to-be-measured coupling strength between the qubit and a read coupling port, based on the read coupling port configuration layout corresponding to the plurality of read coupling ports, the first target frequency, and the intermediate frequency.

10. The method according to claim 1, wherein the calculating a to-be-measured coupling strength between the qubit and the read coupling port, based on the read coupling port configuration layout, the first target frequency, and the second target frequency comprises:
performing electromagnetic simulation on the read coupling port configuration layout to obtain a qubit self-capacitance of the qubit, and a port mutual capacitance between the qubit and the read coupling port; and
taking the qubit self-capacitance, the port mutual capacitance, the first target frequency, and the second target frequency into a port impedance coupling equation to obtain the to-be-measured coupling strength,
wherein the port impedance coupling equation is used to represent a corresponding relationship between all five of the port mutual capacitance, the qubit self-capacitance, a standard impedance, the first target frequency, and the second target frequency, and the to-be-measured coupling strength.

11. The method according to claim 1, wherein generating, based on the second target frequency and the read coupling port configuration layout, a complete layout comprising the qubit and the target read cavity comprises:
completing, in response to detecting that the to-be-measured coupling strength and the target coupling strength satisfy the preset condition, the read coupling port in the read coupling port configuration layout, and generating the complete layout comprising the qubit and the target read cavity.

12. An apparatus for coupling a superconducting qubit, the apparatus comprising:
at least one processor; and
a memory storing instructions, wherein the instructions when executed by the at least one processor, cause the at least one processor to perform operations, the operations comprising:
determining a target coupling strength between a target read cavity and a qubit, a first target frequency of the qubit, and a second target frequency of the target read cavity;
initializing a read coupling port configuration layout based on a configuration of the qubit, a relative position of the qubit to the target read cavity, the read coupling port configuration layout being used to represent a layout of a positional relationship between the qubit and a read coupling port of the target read cavity;
calculating a to-be-measured coupling strength between the qubit and the read coupling port, based on the read coupling port configuration layout, the first target frequency, and the second target frequency; and
in response to detecting that the to-be-measured coupling strength and the target coupling strength satisfy a preset condition, generating, based on the second target frequency and the read coupling port configuration layout, a complete layout comprising the qubit and the target read cavity.

13. The apparatus according to claim 12, wherein the operations further comprise:
adjusting, in response to detecting that the to-be-measured coupling strength and the target coupling strength do not satisfy the preset condition, a spacing between the read coupling port and the qubit in the read coupling port configuration layout, to obtain a new read coupling port configuration layout;
replacing the read coupling port configuration layout with the new read coupling port configuration layout; and
continuing to calculate, based on the new read coupling port configuration layout, the first target frequency and the second target frequency, the to-be-measured coupling strength between the qubit and the read coupling port, until the to-be-measured coupling strength and the target coupling strength are detected to satisfy the preset condition.

14. The apparatus according to claim 12, wherein the operations further comprise:
adjusting, in response to detecting that the to-be-measured coupling strength and the target coupling strength do not satisfy the preset condition, specifications of the read coupling port in the read coupling port configuration layout, to obtain a new read coupling port configuration layout; replacing the read coupling port configuration layout with the new read coupling port configuration layout; and continuing to calculate, based on the new read coupling port configuration layout, the first target frequency and the second target frequency, the to-be-measured coupling strength between the qubit and the read coupling port, until the to-be-measured coupling strength and the target coupling strength are detected to satisfy the preset condition.

15. The apparatus according to claim 14, wherein the read coupling port comprises: a first coupling port of a crossed-finger shape, the first coupling port comprising a first finger portion parallel to a length direction of a capacitance arm of the qubit and the capacitance arm being used for coupling to the read coupling port, and the adjusting, in response to detecting that the to-be-measured coupling strength and the target coupling strength do not satisfy the preset condition, specifications of the read coupling port in the read coupling port configuration layout, to obtain a new read coupling port configuration layout comprises: decreasing, in response to the to-be-measured coupling strength being greater than the target coupling strength by a preset strength value, a length of the first finger portion by a first preset value, to obtain the new read coupling port configuration layout; and increasing, in response to the target coupling strength being greater than the to-be-measured coupling strength by the preset strength value, the length of the first finger portion by the first preset value, to obtain the new read coupling port configuration layout.

16. The apparatus according to claim 14, wherein the read coupling port comprises: a second coupling port of a crossed-finger shape, the second coupling port comprising a second finger portion parallel to a width direction of a capacitance arm of the qubit and the capacitance arm being used for coupling to the read coupling port, and the adjusting, in response to detecting that the to-be-measured coupling strength and the target coupling strength do not satisfy the preset condition, specifications of the read coupling port in the read coupling port configuration layout, to obtain a new read coupling port configuration layout comprises: decreasing, in response to the to-be-measured coupling strength being greater than the target coupling strength by a preset strength value, a width of the second finger portion by a second preset value, to obtain the new read coupling port configuration layout; and increasing, in response to the target coupling strength being greater than the to-be-measured coupling strength by the preset strength value, the width of the second finger portion by the second preset value, to obtain the new read coupling port configuration layout.

17. The apparatus according to claim 12, wherein the operations further comprise:
performing electromagnetic simulation on the complete layout to obtain a qubit self-capacitance of the qubit, and a coupling mutual capacitance between the qubit and the target read cavity; calculating a calculated coupling strength based on the qubit self-capacitance, the coupling mutual capacitance, the first target frequency, and the second target frequency; and determining, in response to detecting that the calculated coupling strength and the target coupling strength satisfy the preset condition, that the complete layout is correct.

18. The apparatus according to claim 17, wherein the calculating a calculated coupling strength based on the qubit self-capacitance, the coupling mutual capacitance, the first target frequency, and the second target frequency comprises: taking the qubit self-capacitance, the coupling mutual capacitance, the first target frequency, and the second target frequency into a read cavity impedance coupling equation to obtain the calculated coupling strength,
wherein the read cavity impedance coupling equation is used to represent a corresponding relationship between all five of the coupling mutual capacitance, the qubit self-capacitance, a standard impedance, the first target frequency, and the second target frequency, and the calculated coupling strength.

19. The apparatus according to claim 12, wherein the determining a target coupling strength between a target read cavity and a qubit, a first target frequency of the qubit, and a second target frequency of the target read cavity comprises: acquiring a preset first target frequency of the qubit and the target coupling strength; and calculating the second target frequency based on the first target frequency and the target coupling strength.

20. A non-transitory computer readable storage medium storing computer instructions, wherein the computer instructions are used to cause a computer to perform operations comprising:
determining a target coupling strength between a target read cavity and a qubit, a first target frequency of the qubit, and a second target frequency of the target read cavity;
initializing a read coupling port configuration layout based on a configuration of the qubit, a relative position of the qubit to the target read cavity, the read coupling port configuration layout being used to represent a layout of a positional relationship between the qubit and a read coupling port of the target read cavity;
calculating a to-be-measured coupling strength between the qubit and the read coupling port, based on the read coupling port configuration layout, the first target frequency, and the second target frequency; and
in response to detecting that the to-be-measured coupling strength and the target coupling strength satisfy a preset condition, generating, based on the second target frequency and the read coupling port configuration layout, a complete layout comprising the qubit and the target read cavity.
